(19) United States
(12) Patent Application Publication
(10) Pub. No.: US 2024/0292604 A1
(43) Pub. Date: Aug. 29, 2024

(54) SEMICONDUCTOR DEVICE

(71) Applicant: Samsung Electronics Co., Ltd., Suwon-si (KR)

(72) Inventors: Jiseong KIM, Suwon-si (KR); JUNSOO KIM, Suwon-si (KR); DAEHYUN MOON, Suwon-si (KR); SUNGHO JANG, Suwon-si (KR)

(21) Appl. No.: 18/386,654

(22) Filed: Nov. 3, 2023

(30) Foreign Application Priority Data
Feb. 24, 2023 (KR) 10-2023-0025029

(51) Int. Cl. H10B 12/00

(52) U.S. Cl. CPC H10B 12/488; H10B 12/315; H10B 12/482

(57) ABSTRACT

A semiconductor device includes a substrate including cell regions, active patterns adjacent to each other in first and second directions that are parallel to a lower surface of the substrate and intersect each other on the cell regions, a shield pattern surrounding side surfaces of the active patterns, a first isolation pattern surrounding the active patterns between the active patterns and the shield pattern, second isolation patterns between adjacent active patterns in the first direction, and word lines crossing the active patterns and the shield pattern in the second direction.

### CROSS-REFERENCE TO RELATED APPLICATIONS

This U.S. non-provisional patent application claims priority under 35 U.S.C. § 119 to Korean Patent Application No. 10-2023-0025029, filed on Feb. 24, 2023, in the Korean Intellectual Property Office, the entire contents of which are hereby incorporated by reference.

### BACKGROUND OF THE INVENTION

The present disclosure relates to a semiconductor, and more particularly, relates to a semiconductor device including a shield pattern.

Due to their relatively small-size, multi-functionality, and/or relatively low-cost characteristics, semiconductor devices are considered important elements in the electronic industry. The semiconductor devices may be classified into a memory device for storing data, a logic device for processing data, and a hybrid device including both memory and logic elements.

Recently, with the high-speed and low-power consumption of electronic devices, semiconductor devices embedded in the electronic devices also require high operating speeds and/or low operating voltages, and more highly integrated semiconductor devices are required to meet these requirements. However, as integration of semiconductor devices intensifies, electrical characteristics and production yield of the semiconductor devices may decrease. Accordingly, many studies are being conducted to improve the electrical characteristics and production yield of semiconductor devices.

### SUMMARY

An object of the present disclosure is to provide a semiconductor device with improved electrical characteristics and reliability.

The problem to be solved by the present disclosure is not limited to the above-mentioned problems, and other problems not mentioned will be clearly understood by those skilled in the art from the following description.

A semiconductor device according to some embodiments of the present disclosure may include a substrate including cell regions, active patterns adjacent to each other in first and second directions that are parallel to a lower surface of the substrate and intersect each other on the cell regions, a shield pattern surrounding side surfaces of the active patterns, a first isolation pattern surrounding the active patterns between the active patterns and the shield pattern, second isolation patterns between adjacent active patterns in the first direction, and word lines crossing the active patterns and the shield pattern in the second direction.

A semiconductor device according to some embodiments of the present disclosure may include a first active pattern and a second active pattern adjacent to each other in a first direction, a device isolation pattern surrounding the first active pattern and the second active pattern, a word line crossing the device isolation pattern in a second direction crossing the first direction between the first active pattern and the second active pattern, and a shield pattern between the first active pattern and the word line and between the second active pattern and the word line.

A semiconductor device according to some embodiments of the present disclosure may include a substrate including a cell region, active patterns adjacent to each other in first to third directions that are parallel to a lower surface of the substrate and intersect each other on the cell region, a shield pattern surrounding side surfaces of the active patterns, a first isolation pattern surrounding the active patterns between the active patterns and the shield pattern, second isolation patterns between adjacent active patterns in the first direction, word lines crossing the active patterns and the shield pattern in the second direction, bit lines extending in the third direction on the active patterns, storage node contacts interposed between adjacent bit lines on the active patterns and adjacent to each other in the second and third directions, landing pads on the storage node contacts, and data storage patterns on the landing pads.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a block diagram illustrating a semiconductor device including according to some example embodiments of the present disclosure.

FIG. 2 is a plan view illustrating a semiconductor device according to some example embodiments of the present disclosure, and is an enlarged view corresponding to PI in FIG. 1.

FIGS. 3A to 3C are cross-sectional views corresponding to lines A-A′, B-B′, and C-C′ of FIG. 2, respectively.

FIGS. 4 to 11C are views illustrating a method of manufacturing a semiconductor device according to some example embodiments of the present disclosure.

### DETAILED DESCRIPTION

Hereinafter, in order to explain the present disclosure in more detail, embodiments according to the present disclosure will be described in more detail with reference to the accompanying drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

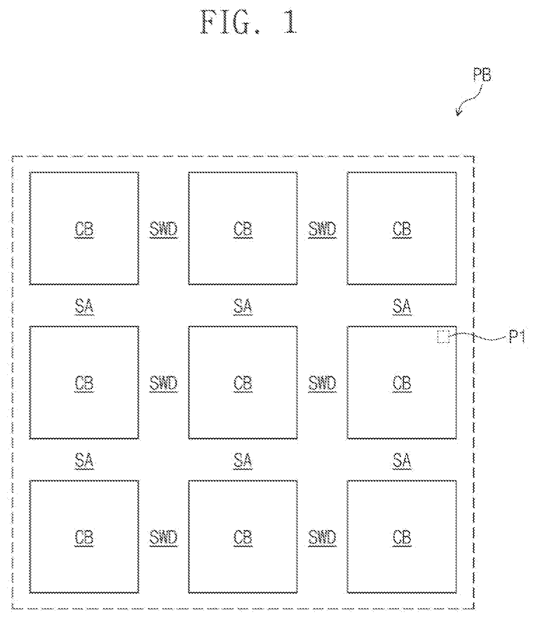

FIG. 1 is a block diagram illustrating a semiconductor device including according to some example embodiments of the present disclosure.

Referring to FIG. 1, a semiconductor device may include cell blocks CB and peripheral blocks PB surrounding each of the cell blocks CB. Each of the cell blocks CB may include a cell circuit such as a memory integrated circuit. The peripheral block PB may include various peripheral circuits necessary for an operation of the cell circuit, and the peripheral circuits may be electrically connected to the cell circuits of the cell blocks CB.

The peripheral block PB may include sense amplifier circuits SA and sub-word line driver circuits SWD. For example, the sense amplifier circuits SA may face each other with the cell blocks CB interposed therebetween, and the sub-word line driver circuits SWD may face each other with the cell blocks CB interposed therebetween. The peripheral block PB may further include a power supply for driving sense amplifiers and ground driver circuits, but the concept of the present disclosure is not limited thereto.

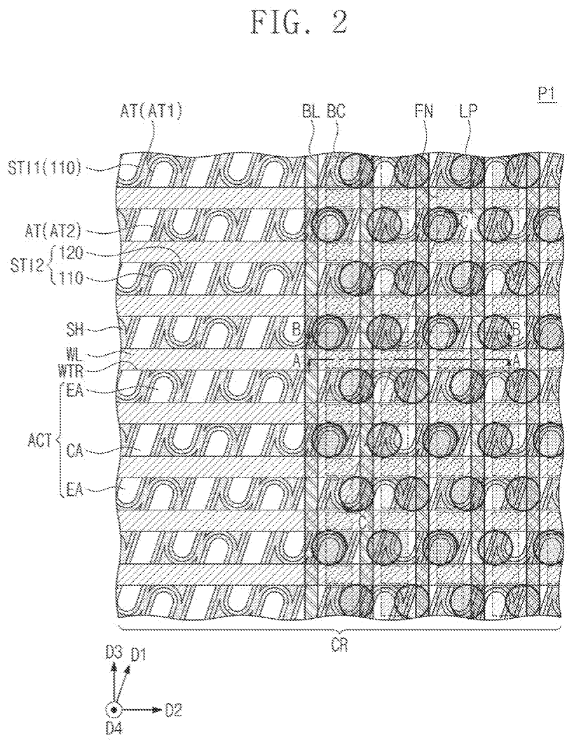

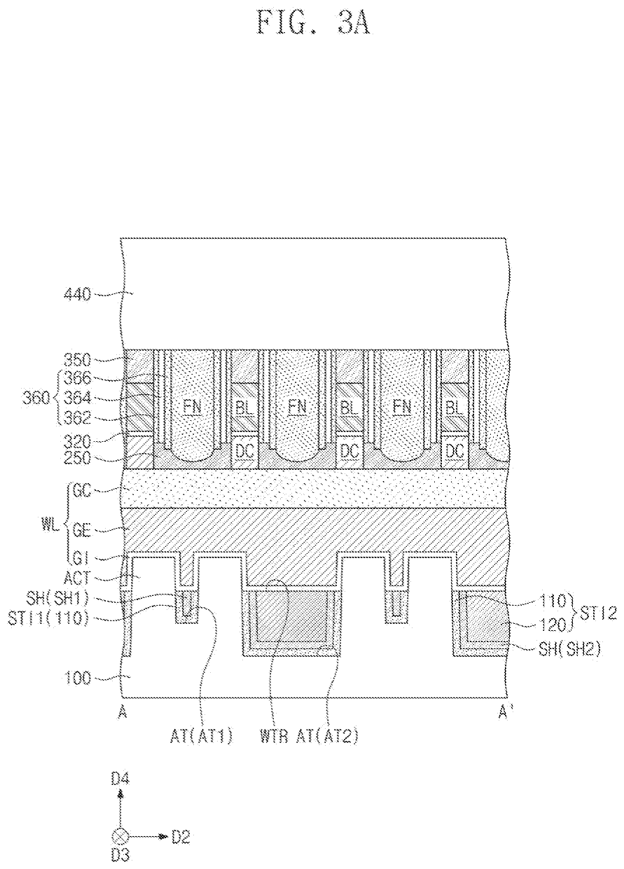

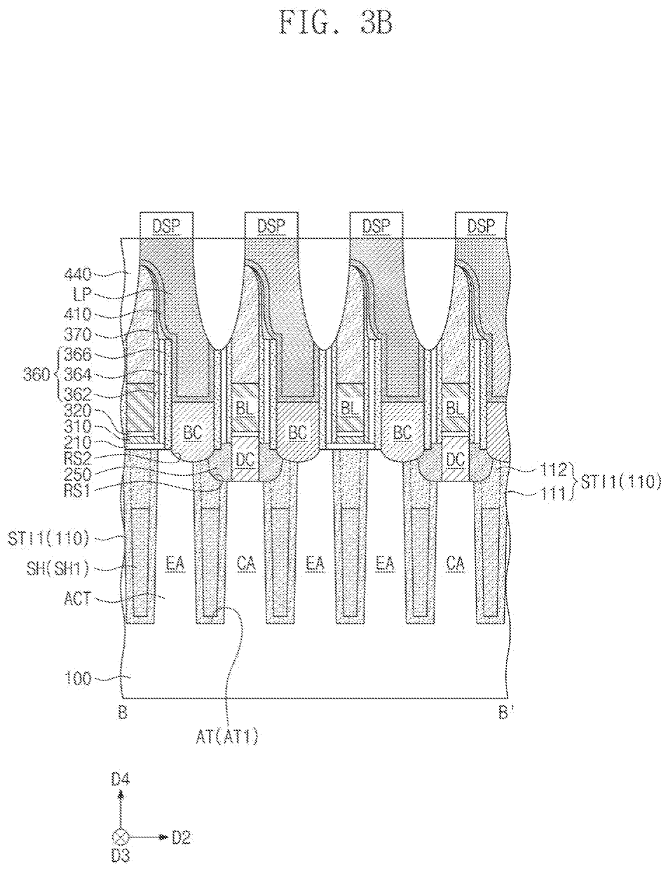

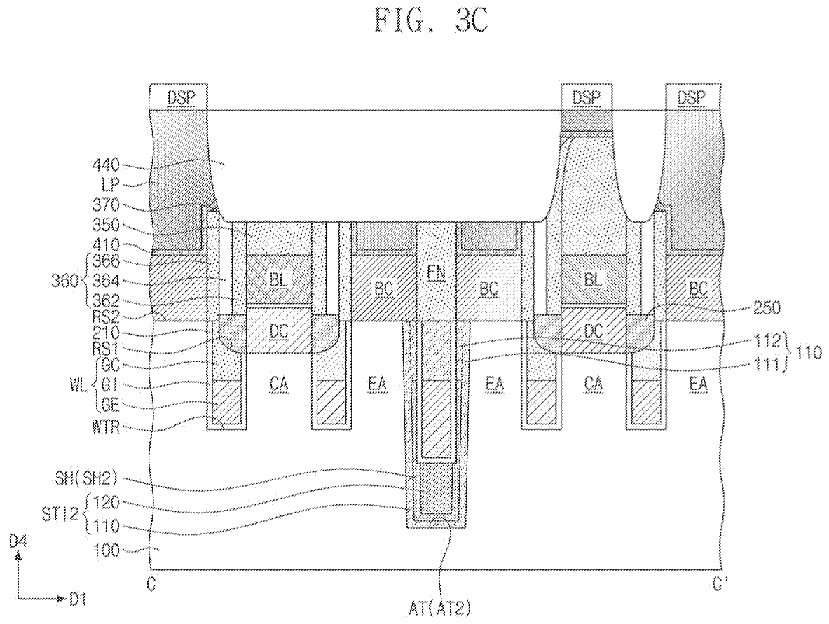

FIG. 2 is a plan view illustrating a semiconductor device according to some example embodiments of the present disclosure, and is an enlarged view corresponding to PI in FIG. 1. FIGS. 3A to 3C are cross-sectional views corresponding to lines A-A′, B-B′, and C-C′ of FIG. 2, respectively.

For ease of understanding, a left area of FIG. 2 shows only a structure of components disposed below an upper surface of the active pattern ACT, which will be described later. Therefore, although not shown, it should be understood that the left area is also provided with the same components disposed above the upper surface of the active pattern ACT, which will be described later, as a right area.

Referring to FIGS. 2 to 3C, a substrate 100 may be provided. The substrate 100 may be one of a semiconductor substrate, for example, a silicon substrate, a germanium substrate, and a silicon-germanium substrate. In the present specification, each of phrases such as “A or B”, “at least one of A and B”, “at least one of A or B”, “A, B or C”, “at least one of A, B and C”, and “at least one of A, B, or C” may include one of the items listed together in the corresponding phrase among those phrases, or all possible combinations thereof.

The substrate 100 may include cell regions CR and a peripheral region (not shown). Each of the cell regions CR may be one region of the substrate 100 provided with the cell block CB of FIG. 1. The peripheral region may be the other region of the substrate 100 provided with the peripheral block PB of FIG. 1. The peripheral region may surround each of the cell regions CR.

Active patterns ACT may be provided on the cell region CR. Each of the active patterns ACT may extend lengthwise in a first direction D1 parallel to a lower surface of the substrate 100. Each of the active patterns ACT may include a center portion CA and an edge portion EA. For example, each of the active patterns ACT may include a center portion CA and a pair of edge portions EA spaced apart from each other in the first direction D1 with the center portion CA interposed therebetween. The pair of edge portions EA may be both ends of the active pattern ACT in the first direction D1. For example, a first one of the pair of edge portions EA may be at a first end of the active pattern ACT, a second one of the pair of edge portions EA may be at a second end of the active pattern ACT, and the center portion CA may be interposed between the first and second ones of the pair of edges portions EA. The center portion CA may be interposed between a pair of word lines WL that will be described later crossing the active pattern ACT. Impurities (e.g., n-type or p-type impurities) may be provided in the center portion CA and the edge portion EA.

The active patterns ACT may be adjacent to each other in first to third directions D1, D2, and D3. The second and third directions D2 and D3 may be directions that are parallel to the lower surface of the substrate 100 and cross the first direction D1, respectively. In the present specification, when the active patterns ACT are adjacent to each other in the first direction D1, it means that the center portions CA of the active patterns ACT adjacent to each other are disposed in the first direction D1. In the present specification, when the active patterns ACT are adjacent to each other in the second direction D2, it means that one center portion CA and the other edge portion EA among the active patterns ACT adjacent to each other are disposed in the second direction D2. In the present specification, when the active patterns ACT are adjacent to each other in the third direction D3, it means that the center portions CA of the active patterns ACT adjacent to each other are disposed in the third direction D3.

The active patterns ACT may include a portion of the substrate 100 surrounded by device isolation patterns STI1 and STI2 to be described later. For convenience of explanation, in this specification, unless otherwise specified, the substrate 100 is defined as referring to other portions of the substrate 100 other than the portions (i.e., the active patterns ACT). The active patterns ACT may protrude in a fourth direction D4 perpendicular to the lower surface of the substrate 100.

An active trench region AT may be defined between the active patterns ACT. The active trench region AT may be defined by the active patterns ACT and the substrate 100. The active trench region AT may include a first active trench region AT1 and a second active trench region AT2. For example, the first active trench region AT1 may be disposed between active patterns ACT neighboring in the second direction D2 or the third direction D3. For example, the second active trench region AT2 may be disposed between active patterns ACT neighboring in the first direction D1.

A first isolation pattern 110, a second isolation pattern 120, and a shield pattern SH may be located in the active trench region AT. For example, the first isolation pattern 110 may be disposed within the first active trench region AT1 and the second active trench region AT2. For example, the second isolation pattern 120 may be disposed within the second active trench region AT2. As another example, the second isolation pattern 120 may not be disposed within the first active trench region AT2. For example, the shield pattern SH may be disposed within the first active trench region AT1 and the second active trench region AT2.

The first isolation pattern 110 may cover inner walls of the first active trench region AT1 and inner walls of the second active trench region AT2. For example, the first isolation pattern 110 may conformally cover at least a portion of the inner wall of the first active trench region AT1 and at least a portion of the inner wall of the second active trench region AT2. The first isolation pattern 110 may contact at least a portion of the inner wall of the first active trench region AT1 and at least a portion of the inner wall of the second active trench region AT2. The first isolation pattern 110 may include first sub-isolation patterns 111 on lower and side surfaces of the shield pattern SH and second sub-isolation patterns 112 on an upper surface of the shield pattern SH. The first sub-isolation pattern 111 may cover the side surface of the shield pattern SH and may be interposed between the side surface of the shield pattern SH and the active pattern ACT. For example, the first sub-isolation pattern 111 may contact the side surface of the shield pattern SH. The second sub-isolation pattern 112 may cover the upper surface of the shield pattern SH. For example, the second sub-isolation pattern 112 may contact the upper surface of the shield pattern SH. For example, the first sub-isolation pattern 111 and the second sub-isolation pattern 112 may be in contact with each other without a boundary, but is not limited thereto.

The second isolation pattern 120 may fill the inside of the second active trench region AT2. For example, the second isolation pattern 120 may fill at least a portion (e.g., a lower portion) of the second active trench region AT2. For example, the second isolation pattern 120 may fill the inside of the second active trench region AT2 on the first isolation pattern 110. The second isolation patterns 120 may be provided in plural, and each of the second isolation patterns 120 may fill the corresponding second active trench region AT2.

The first isolation pattern 110 and the second isolation pattern 120 may independently include silicon oxide or silicon nitride. For example, the first isolation pattern 110 may include silicon oxide, and the second isolation pattern 120 may include silicon nitride.

The shield pattern SH may include a first shield pattern SH1 in the first active trench region AT1 and a second shield pattern SH2 in the second active trench region AT2. For example, the first shield pattern SH1 may be surrounded by the first isolation pattern 110 and may fill at least a portion (e.g., a lower portion) of the first active trench region AT1. For example, the second shield pattern SH2 may be interposed between the first isolation pattern 110 and the second isolation pattern 120 and conformally cover the inner wall of the second active trench region AT2.

For example, the shield pattern SH may include a conductive material. For example, the shield pattern SH may include polysilicon containing impurities. As another example, the shield pattern SH may include at least one of a metal material (e.g., Ti, Mo, W, Cu, Al, Ta, Ru, Ir, La, etc.), a metal oxide (e.g., oxides of Ti, Mo, W, Cu, Al, Ta, Ru, Ir, La, etc.), and metal nitrides (e.g., nitrides of Ti, Mo, W, Cu, Al, Ta, Ru, Ir, La, etc.)

When viewed in a plan view, the shield pattern SH may surround the active patterns ACT. For example, one shield pattern SH may surround side surfaces of two or more active patterns ACT on one cell region CR. For example, one shield pattern SH may surround side surfaces of all active patterns ACT on one cell region CR. For example, one shield pattern SH may be continuously connected in the first active trench region AT1 and the second active trench region AT2 on one cell region CR.

The one shield pattern SH may include one or more first shield patterns SH1 and one or more second shield patterns SH2 electrically connected to each other. The one shield pattern SH may be electrically connected to one contact pattern (not shown) and electrically controlled through the contact pattern. For example, the one contact pattern may be provided on the peripheral region, but the concept of the present disclosure is not limited thereto.

The first isolation pattern 110 may surround the active patterns ACT between each of the active patterns ACT and the shield pattern SH. The shield pattern SH may surround the second isolation pattern 120 in the second active trench region AT2.

Within the active trench region AT, device isolation patterns STI1 and STI2 may be defined by the first isolation pattern 110 and the second isolation pattern 120. For example, the first device isolation pattern STI1 may be defined within the first active trench region AT1 and may include the first isolation pattern 110 within the first active trench region AT1. For example, the second device isolation pattern STI2 may be defined in the second active trench region AT2 and may include the first isolation pattern 110 and the second isolation pattern 120 in the second active trench region AT2. The device isolation patterns STI1 and STI2 may surround the shield pattern SH. The device isolation patterns STI1 and STI2 may be interposed between the active pattern ACT and the shield pattern SH, and may surround the active pattern ACT.

A word line WL may cross the active patterns ACT, the device isolation patterns STI1 and STI2, and the shield pattern SH. The word line WL may be provided in plural, and each of the plurality of word lines WL may cross the active patterns ACT, the device isolation patterns STI1 and STI2, and the shield pattern SH. The word lines WL may each extend lengthwise in the second direction D2 and may be spaced apart from each other in the third direction D3. For example, a pair of word lines WL spaced apart from each other in the third direction D3 may cross the active pattern ACT in the second direction D2. The word lines WL may be spaced apart from each other in the third direction D3 with the shield pattern SH interposed therebetween.

The word line WL may extend between adjacent active patterns ACT in the first direction D1 (i.e., in the second active trench region AT2). The word line WL may be spaced apart from the neighboring active patterns ACT with the shield pattern SH therebetween (refer to FIGS. 2 and 3C). The word line WL may be provided in a word line trench WTR. The shield pattern SH may be provided on a side of the word line WL. For example, the shield pattern SH may cover at least a portion of the side surface of the word line WL. For example, an uppermost surface of the shield pattern SH may be positioned at a higher level than a lowermost surface of the word line WL. For example, the second isolation pattern 120 may be interposed between a lower surface of the word line WL and the shield pattern SH.

The shield pattern SH may cover a side surface of each of the word lines WL. For example, one shield pattern SH may cover each side of two or more word lines WL on one cell region CR. For example, one shield pattern SH may cover each side surface of all word lines WL on one cell region CR.

Each of the word lines WL may include a gate electrode GE, a gate dielectric pattern GI, and a gate capping pattern GC. The gate electrode GE may pass through the active patterns ACT and the device isolation patterns STI1 and STI2 in the second direction D2. The gate dielectric pattern GI may be interposed between the gate electrode GE and the active patterns ACT and between the gate electrode GE and the shield pattern SH. The gate capping pattern GC may cover an upper surface of the gate electrode GE on the gate electrode GE. For example, the gate electrode GE may include a conductive material. For example, the gate dielectric pattern GI may include at least one of silicon oxide and a high-k material. In this specification, a high-k material is defined as a material having a higher dielectric constant than that of silicon oxide. For example, the gate capping pattern GC may include silicon nitride.

According to the concept of the present disclosure, the word lines WL may be spaced apart from each other with the shield pattern SH interposed therebetween. The shield pattern SH may include a conductive material, and thus interference between word lines WL may be minimized. In addition, one shield pattern SH may surround the plurality of active patterns ACT on the cell region CR and may cover the side surfaces of each of the word lines WL. Accordingly, the shield pattern SH may be electrically easily controlled. As a result, electrical characteristics and reliability of the semiconductor device may be improved.

A buffer pattern 210 may be disposed on the substrate 100. The buffer pattern 210 may cover the active patterns ACT, the device isolation patterns STI1 and STI2, and the word lines WL. For example, the buffer pattern 210 may include at least one of silicon oxide, silicon nitride, silicon oxynitride, or a combination thereof. The buffer pattern 210 may be a single layer formed of a single material or a composite layer including two or more materials.

A bit line contact DC may be provided on each of the active patterns ACT, and may be provided in plural. The bit line contacts DC may be electrically connected to the center portions CA of the active patterns ACT, respectively. The bit line contacts DC may be spaced apart from each other in second and third directions D2 and D3. The bit line contacts DC may be interposed between the active patterns ACT and bit lines BL, which will be described later. The bit line contacts DC may electrically connect a corresponding bit line BL among the bit lines BL and the center portions CA of the corresponding active patterns ACT.

The bit line contacts DC may be disposed in a first recess regions RS1, respectively. The first recess regions RS1 may be provided above the active patterns ACT and above the device isolation patterns STI1 and STI2 adjacent to upper portions of the active patterns ACT. The first recess regions RS1 may be spaced apart from each other in second and third directions D2 and D3.

A buried insulating pattern 250 may fill each of the first recess regions RS1. The buried insulating pattern 250 may fill the inside of the first recess region RS1. For example, the buried insulating pattern 250 may cover an inner surface of the first recess region RS1 and at least a portion (e.g., a bit line contact DC within the first recess region RS1) of a side surface of the bit line contact DC. The buried insulating pattern 250 may include at least one of silicon oxide, silicon nitride, or a combination thereof. The buried insulating pattern 250 may be a single layer formed of a single material or a composite layer including two or more materials.

A bit line BL may be provided on the bit line contact DC. The bit line BL may extend lengthwise in the third direction D3. The bit line BL may be disposed on a row of bit line contacts DC disposed in the third direction D3. The bit line BL may be provided in plural. The bit lines BL may be spaced apart from each other in the second direction D2. The bit line BL may include a metal material. For example, the bit line BL may include a metal material (e.g., Ti, Mo, W, Cu, Al, Ta, Ru, Ir, etc.).

A polysilicon pattern 310 may be provided between the bit line BL and the buffer pattern 210. The polysilicon pattern 310 may be provided in plural. For example, an upper surface of the polysilicon pattern 310 may be positioned at substantially the same height as an upper surface of the bit line contact DC, but is not limited thereto. The polysilicon pattern 310 may include polysilicon doped with impurities.

A first ohmic pattern 320 may be interposed between the bit line BL and the bit line contact DC and between the bit line BL and the polysilicon pattern 310. The first ohmic pattern 320 may extend lengthwise in the third direction D3 along the bit line BL. The first ohmic pattern 320 may be provided in plural. The plurality of first ohmic patterns 320 may be spaced apart from each other in the second direction D2. The first ohmic pattern 320 may include metal silicide. A first barrier pattern (not shown) may be further interposed between the bit line BL and the bit line contact DC and between the bit line BL and the polysilicon pattern 310. The first barrier pattern may include a conductive metal nitride (e.g., nitride of Ti, Mo, W, Cu, Al, Ta, Ru, Ir, etc.).

A bit line capping pattern 350 may be provided on an upper surface of the bit line BL. The bit line capping pattern 350 may contact the upper surface of the bit line BL. The bit line capping pattern 350 may extend lengthwise in the third direction D3 on the upper surface of the bit line BL. The bit line capping pattern 350 may be provided in plural. The plurality of bit line capping patterns 350 may be spaced apart from each other in the second direction D2. The bit line capping pattern 350 may vertically overlap the bit line BL. The bit line capping pattern 350 may include a single layer or multiple layers. For example, the bit line capping pattern 350 may include a first capping pattern, a second capping pattern, and a third capping pattern sequentially stacked. The first to third capping patterns may include the same or different materials, and for example, each of the first to third capping patterns may include silicon nitride. As another example, the bit line capping pattern 350 may include capping patterns stacked in four or more layers.

Bit line spacers 360 may be provided on a side surface of the bit line BL and a side surface of bit line capping pattern 350. The bit line spacer 360 may cover the side surface of the bit line BL and the side surface of the bit line capping pattern 350. The bit line spacer 360 may contact the side surface of the bit line BL and the side surface of bit line capping pattern 350. The bit line spacer 360 may extend in the third direction D3 on the side surface of the bit line BL.

The bit line spacer 360 may include a plurality of spacers. For example, the bit line spacer 360 may include a first spacer 362, a second spacer 364, and a third spacer 366. The third spacer 366 may be provided on the side of the bit line BL and the side of the bit line capping pattern 350. The first spacer 362 may be interposed between the bit line BL and the third spacer 366 and between the bit line capping pattern 350 and the third spacer 366. The first spacer 362 may contact the bit line BL and the bit line capping pattern 350. The second spacer 364 may be interposed between the first spacer 362 and the third spacer 366. The second spacer 364 may be contact a side surface of the first spacer 362 and a side surface of the third spacer 366. For example, each of the first to third spacers 362, 364, and 366 may independently include at least one of silicon nitride, silicon oxide, silicon oxycarbide, and silicon oxycarbonitride. As another example, the second spacer 364 may include a kind of air gap separating the first and third spacers 362 and 366 from each other. The term “air” as discussed herein, may refer to atmospheric air, or other gases that may be present during the manufacturing process.

For example, the capping spacer 370 may be disposed on the bit line spacer 360. The capping spacer 370 may cover an upper portion of a side surface of the bit line spacer 360. The capping spacer 370 may include, for example, silicon nitride. However, the concept of the present disclosure is not limited thereto, and as another example, the capping spacer 370 may not be provided.

A storage node contact BC may be provided between adjacent bit lines BL. For example, the storage node contact BC may be interposed between adjacent bit line spacers 360. The storage node contact BC may contact each of the adjacent bit line spacers 360. The storage node contacts BC may be provided in plural. The plurality of storage node contacts BC may be spaced apart from each other in second and third directions D2 and D3. The storage node contacts BC adjacent to each other in the second direction D2 may be spaced apart from each other with the bit line BL interposed therebetween. The storage node contacts BC adjacent to each other in the third direction D3 may be spaced apart from each other with fence patterns FN on the word lines WL interposed therebetween.

The storage node contacts BC may fill second recess regions RS2 provided on the edge portions EA of the active patterns ACT, respectively. Each of the storage node contacts BC may be electrically connected to a corresponding edge portion EA. The storage node contact BC may include at least one of polysilicon doped or undoped with impurities and a metal material.

The fence pattern FN may be provided between adjacent bit lines BL. The fence pattern FN may be provided in plural. The fence patterns FN may be spaced apart from each other in second and third directions D2 and D3. The fence patterns FN adjacent to each other in the second direction D2 may be spaced apart from each other with the bit line BL interposed therebetween. The fence patterns FN may contact adjacent bit line spacers 360. For example, the fence patterns FN may contact side surfaces of the third spacers 366. The fence patterns FN adjacent to each other in the third direction D3 may be spaced apart from each other with the storage node contact BC therebetween. The fence patterns FN may contact adjacent storage node contacts BC. The fence patterns FN may include, for example, at least one of silicon oxide, silicon nitride, silicon oxycarbide, and silicon oxycarbonitride.

A second barrier pattern 410 may conformally cover the bit line spacer 360, the fence pattern FN, and the storage node contact BC. For example, the second barrier pattern 410 may contact side and upper surfaces of the bit line spacer 360, side surfaces of the fence pattern FN, and an upper surface of the storage node contact BC. The second barrier pattern 410 may include a conductive metal nitride (e.g., nitrides of Ti, Mo, W, Cu, Al, Ta, Ru, or Ir). A second ohmic pattern (not shown) may be further interposed between the second barrier pattern 410 and the storage node contact BC. The second ohmic pattern may include metal silicide.

A landing pad LP may be provided on the storage node contact BC. The landing pad LP may be provided in plural. The plurality of landing pads LP may be spaced apart from each other in first and second directions D1 and D2. The landing pad LP may be connected to a corresponding storage node contact BC. The landing pad LP may cover an upper surface of the bit line capping pattern 350. For example, a lower portion of the landing pad LP may vertically overlap the storage node contact BC, and an upper portion of the landing pad LP may shift from the lower portion in the second direction D2. However, it is not limited thereto. For example, the landing pad LP may include a metal material (e.g., Ti, Mo, W, Cu, Al, Ta, Ru, Ir, etc.).

The filling pattern 440 may cover the landing pad LP. The filling pattern 440 may be interposed between adjacent landing pads LP. The filling pattern 440 may contact the landing pads LP. When viewed in a plan view, the filling pattern 440 may have a mesh shape including holes passing through the landing pads LP. For example, the filling pattern 440 may include at least one of silicon nitride, silicon oxide, silicon oxynitride, or a combination thereof. As another example, the filling pattern 440 may include an empty space (i.e., an air gap) including an air layer.

A data storage pattern DSP may be provided on the landing pad LP. The data storage pattern DSP may be provided in plural. The plurality of data storage patterns DSP may be spaced apart from each other in second and third directions D2 and D3. Each of the data storage patterns DSP may be electrically connected to a corresponding edge portion EA through a corresponding landing pad LP and a corresponding storage node contact BC.

The data storage pattern DSP may be, for example, a capacitor including a lower electrode, a dielectric layer, and an upper electrode. In this case, the semiconductor memory device according to the present disclosure may be a dynamic random access memory (DRAM). As another example, the data storage pattern DSP may include a magnetic tunnel junction pattern. In this case, the semiconductor memory device according to the present disclosure may be a magnetic random access memory (MRAM). As another example, the data storage pattern DSP may include a phase change material or a variable resistance material. In this case, the semiconductor memory device according to the present disclosure may be a phase-change random access memory (PRAM) or a resistive random access memory (ReRAM). However, this is only exemplary and the present disclosure is not limited thereto, and the data storage pattern DSP may include various structures and/or materials capable of storing data.

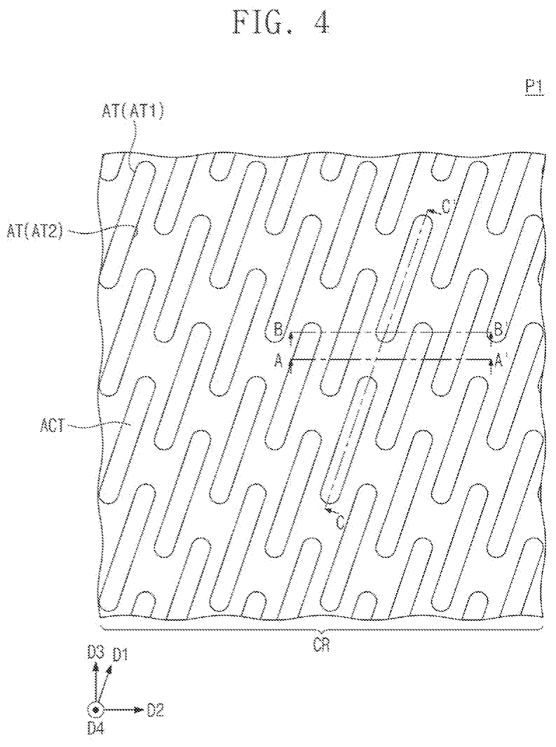

Hereinafter, a method of manufacturing a semiconductor device according to some example embodiments of the present disclosure will be described with reference to FIGS. 4 to 11C. For simplification of the description, descriptions of overlapping contents with the above contents will not be repeated, and differences from the above contents will be mainly described.

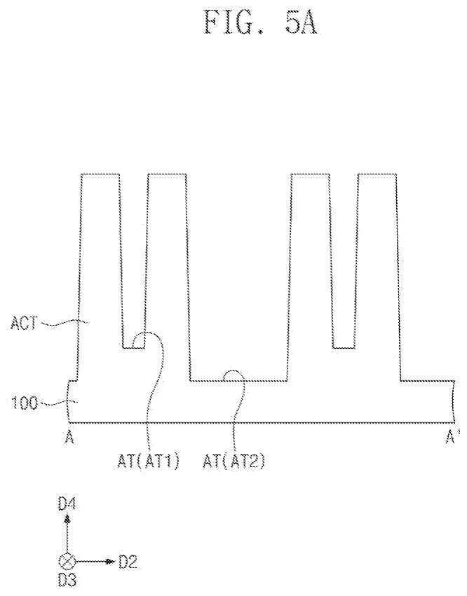

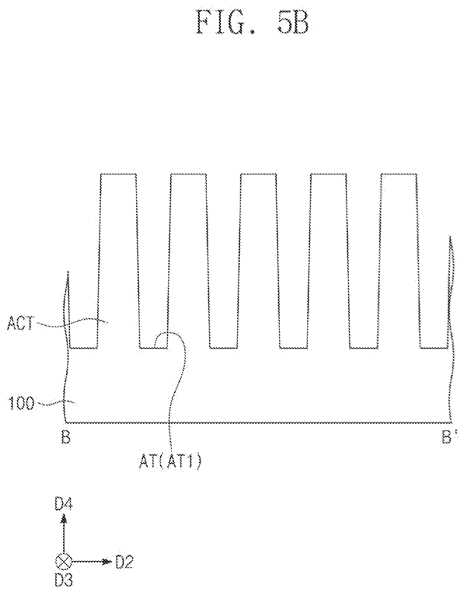

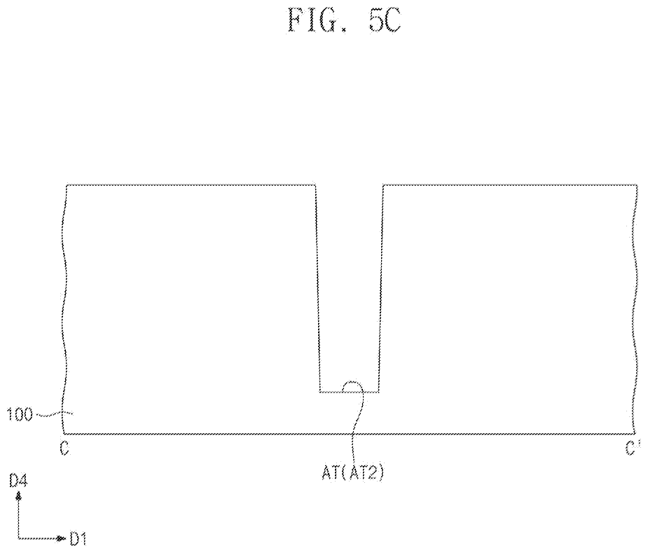

FIGS. 4 to 11C are views illustrating a method of manufacturing a semiconductor device according to some embodiments of the present disclosure. More specifically, FIGS. 4, 6, 8 and 10 are enlarged views corresponding to PI in FIG. 1. FIGS. 5A, 7A, 9A, and 11A are cross-sectional views corresponding to lines A-A′ of FIGS. 4, 6, 8, and 10, respectively. FIGS. 5B, 7B, 9B, and 11B are cross-sectional views corresponding to lines B-B′ of FIGS. 4, 6, 8, and 10, respectively. FIGS. 5C, 7C, 9C, and 11C are cross-sectional views corresponding to lines C-C′ of FIGS. 4, 6, 8, and 10, respectively.

Referring to FIGS. 4 to 5C, a substrate 100 including the cell region CR may be prepared. A removal process may be performed on the substrate 100, and through this, active patterns ACT and active trench regions AT may be formed. The active trench region AT may include a first active trench region AT1 and a second active trench region AT2. A lower surface of the first active trench region AT1 may be at a higher vertical level (e.g., a level in the fourth direction D4) than a lower surface of the second active trench region AT2.

The removal process may include forming mask patterns on the substrate 100 using an exposure process, and etching the substrate 100 using the mask patterns as an etching mask. For example, the exposure process and the etching process may be alternately repeated a plurality of times. For example, the exposure process may be an exposure process using extreme ultraviolet (EUV).

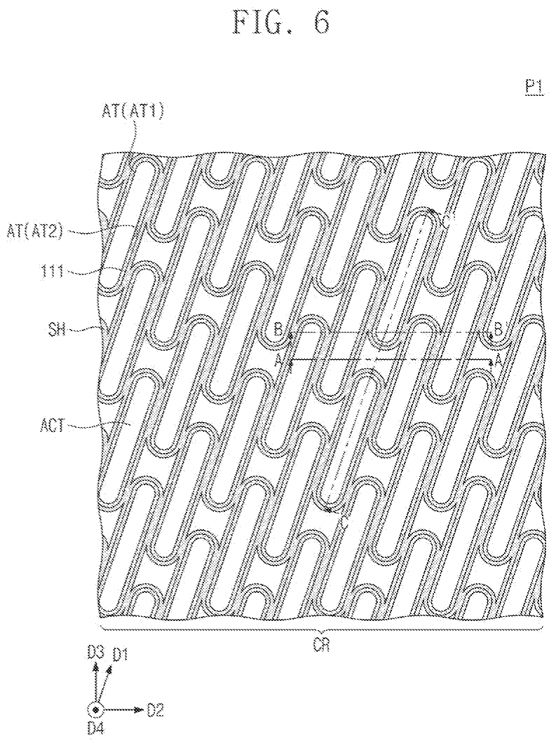

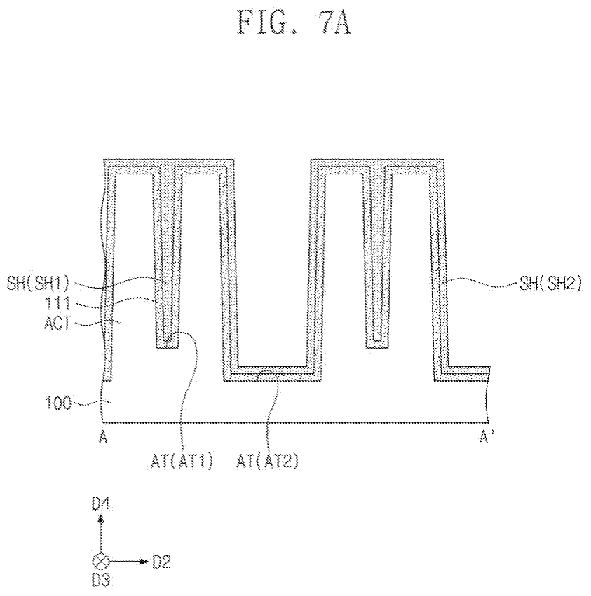

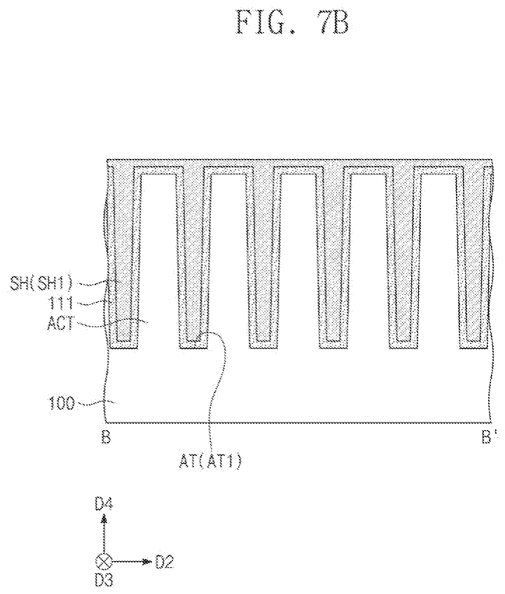

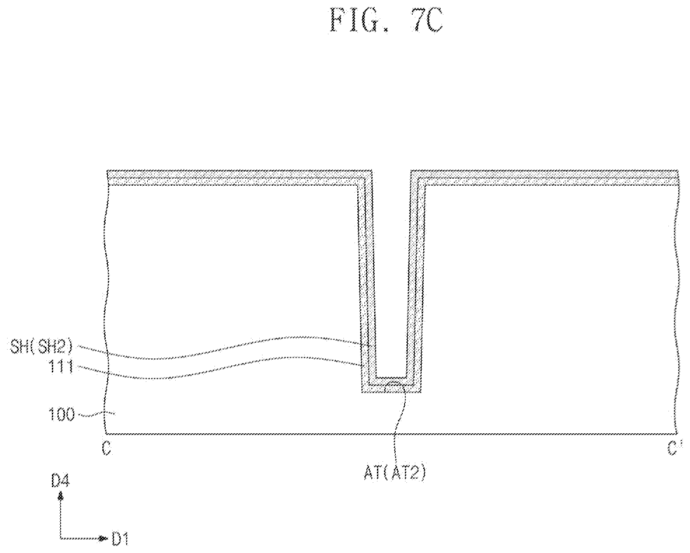

Referring to FIGS. 6 to 7C, a first sub-isolation pattern 111 may be formed on the entire surface of the substrate 100. For example, the first sub-isolation pattern 111 may conformally cover an inner wall of the active trench region AT and upper surfaces of the active patterns ACT. The first sub-isolation pattern 111 may contact the inner wall of the active trench region AT and the upper surfaces of the active patterns ACT. The first sub-isolation pattern 111 may have a substantially uniform thickness. The first sub-isolation pattern 111 may surround each of the active patterns ACT. The first sub-isolation pattern 111 may fill at least a portion of the active trench region AT. For example, the first sub-isolation pattern 111 may not fill another portion of the active trench region AT. A lower surface of the first sub-isolation pattern 111 formed in the first active trench region AT1 may be at a higher vertical level (e.g., a level in the fourth direction D4) than a lower surface of the first sub-isolation pattern 111 formed in the second active trench region AT2.

A shield pattern SH may be formed on the entire surface of the substrate 100. For example, the shield pattern SH may cover the inner wall of the active trench region AT and upper surfaces of the active patterns ACT on the first sub-isolation pattern 111. The shield pattern SH may contact an upper surface of the first sub-isolation pattern 111. The shield pattern SH may include a first shield pattern SH1 and a second shield pattern SH2. The first shield pattern SH1 may fill an inside of the first active trench region AT1. For example, the first shield pattern SH1 may fill a remainder of the first active trench region AT1 that is not filled with the first sub-isolation pattern 111. The second shield pattern SH2 may conformally cover an inner wall of the second active trench region AT2. The second shield pattern SH2 may fill at least a portion of an inside of the second active trench region AT2. For example, the second shield pattern SH2 may not fill the other portion of the second active trench region AT2. A lower surface of the first shield pattern SH1 formed in the first active trench region AT1 may be at a higher vertical level (e.g., a level in the fourth direction D4) than a lower surface of the second shield pattern SH2 formed in the second active trench region AT2.

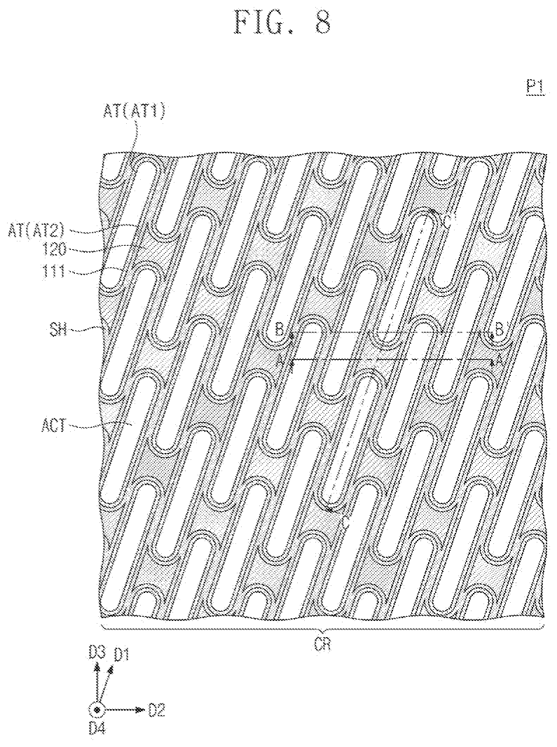

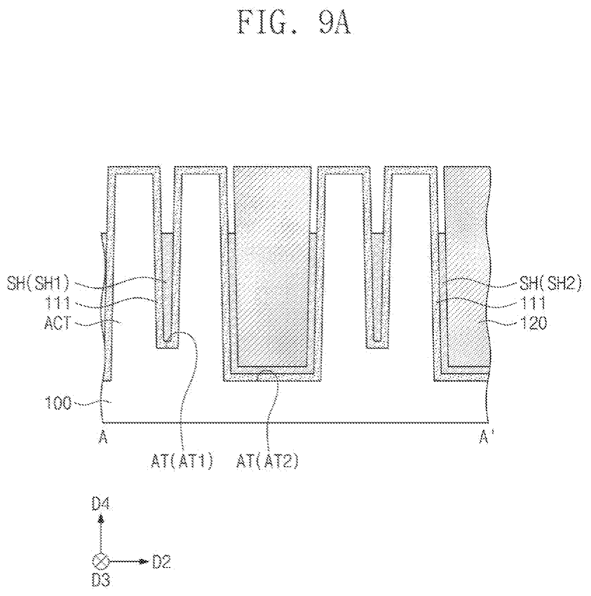

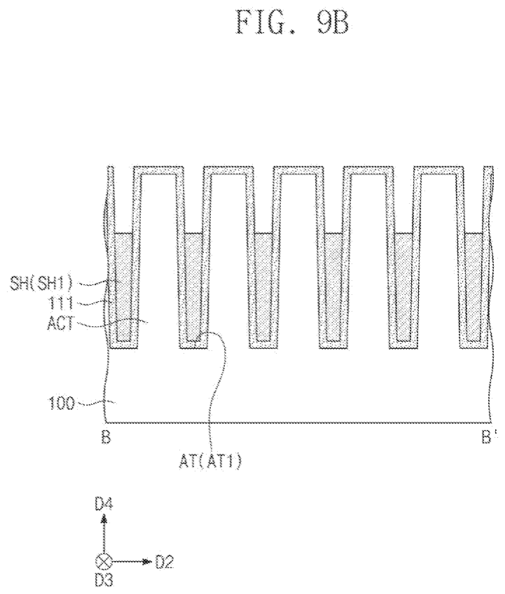

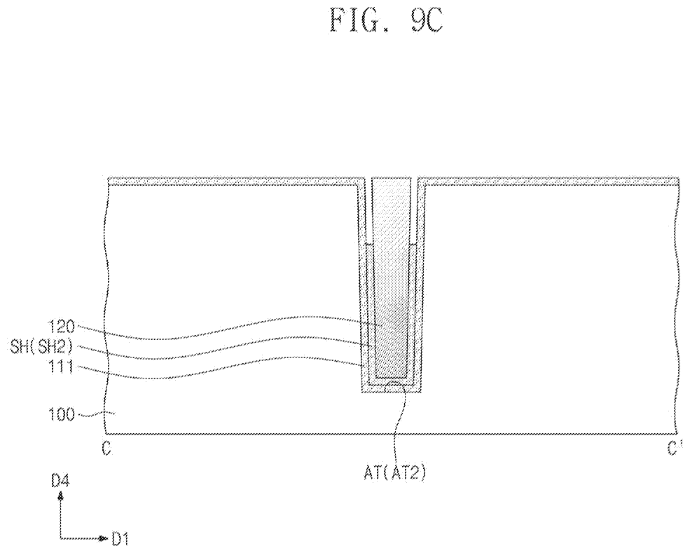

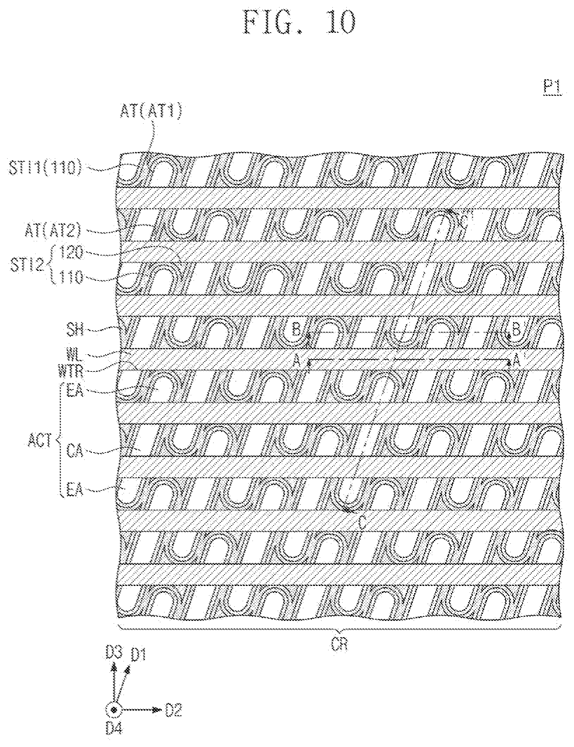

Referring to FIGS. 8 to 9C, a second isolation pattern 120 may be formed inside the second active trench region AT2 and on the upper surfaces of the active patterns ACT. The second isolation pattern 120 may fill a remainder of the second active trench region AT2 that is not filled with the first sub-isolation pattern 111 and the shield pattern SH. For example, the second isolation pattern 120 may not be formed inside the first active trench region AT1. The second isolation pattern 120 may cover the inner wall of the second active trench region AT2 and the shield pattern SH on the upper surfaces of the active patterns ACT.

Thereafter, the second isolation pattern 120 may be removed from the upper surfaces of the active patterns ACT. Removing the second isolation pattern 120 may include performing a strip process. Through the removing of the second isolation pattern 120, the shield pattern SH may be exposed on the upper surfaces of the active patterns ACT.

Portions of the shield pattern SH may be removed. Removing the shield pattern SH may include performing an etch-back process on the shield pattern SH. Through the removing portions of the shield pattern SH, an upper portion of the shield pattern SH may be removed, and empty spaces may be formed in the active trench region AT. For example, through the removing portions of the shield pattern SH, an upper portion of the first shield pattern SH1 may be removed, and the empty space may be formed in the first active trench region AT1. For example, through the removing portions of the shield pattern SH, an upper portion of the second shield pattern SH2 may be removed, and the empty space may be formed in the second active trench region AT2. For example, the empty space in the second active trench region AT2 may be formed between the first sub-isolation pattern 111 and the second isolation pattern 120. For example, through the removing portions of the shield pattern SH, the first sub-isolation pattern 111 may be exposed on the upper surfaces of the active patterns ACT.

Through the removing portions of the shield pattern SH, a position of an upper surface of the shield pattern SH may be controlled. When the upper surface of the shield pattern SH is formed at a relatively low level, influence of a voltage applied to the shield pattern SH during operation of the semiconductor device may be minimized. Accordingly, write operation of the semiconductor device may be improved. When the upper surface of the shield pattern SH is formed at a relatively high level, interference between word lines WL may be easily prevented. As a result, characteristics of the semiconductor device may be easily controlled through the removing of the shield pattern SH.

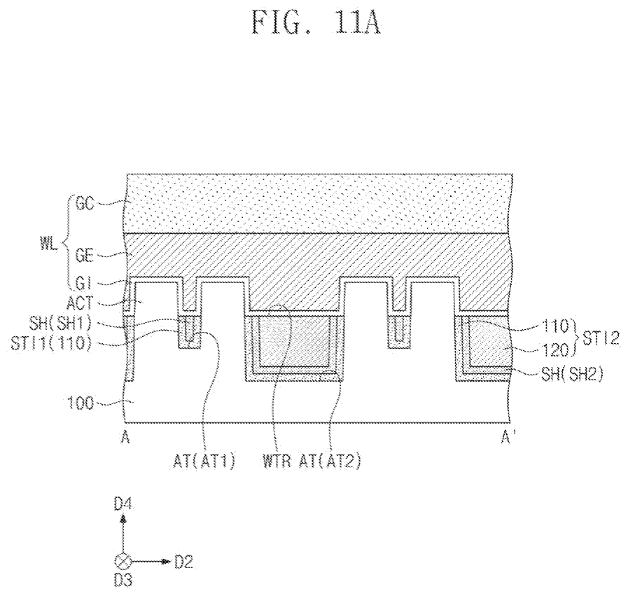

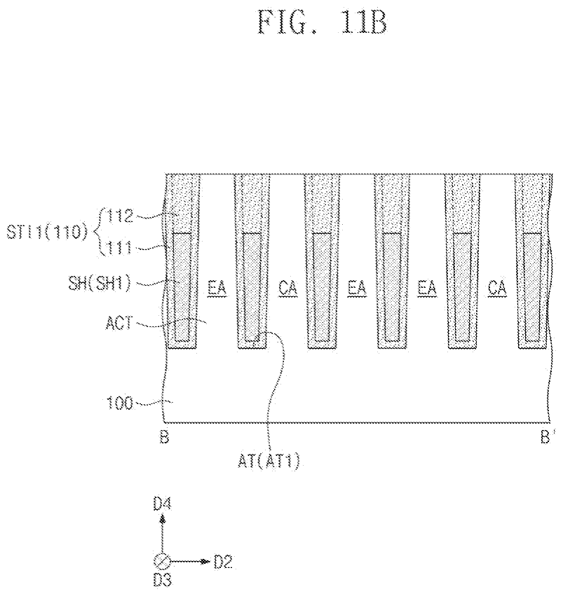

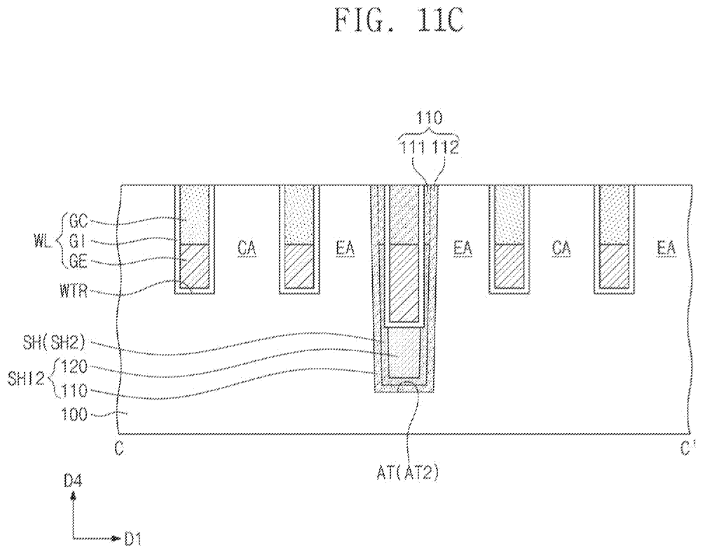

Referring to FIGS. 10 to 11C, a second sub-isolation pattern 112 may be formed in the active trench region AT. The second sub-isolation pattern 112 may fill the empty space in the active trench region AT formed by removing an upper portion of the shield pattern SH. For example, the second sub-isolation pattern 112 may cover the upper surface of the shield pattern SH exposed by the empty space. The second sub-isolation pattern 112 may be further formed on the upper surfaces of the active patterns ACT. For example, the second sub-isolation pattern 112 may cover the first sub-isolation pattern 111 on the upper surfaces of the active patterns ACT. Upper surfaces of the second sub-isolation pattern 112 and the first sub-isolation pattern 111 may be coplanar. For example, the second sub-isolation pattern 112 may be in contact with the first sub-isolation pattern 111 without a boundary.

A word line WL may be formed. The word line WL may be formed to cross the active patterns ACT. Forming the word line WL may include forming a mask pattern on the active patterns ACT, performing an anisotropic etching process using the mask pattern to form a word line trench WTR, and filling the word line trench WTR with the word line WL.

The plurality of word lines WL may each extend in the second direction D2 within the active patterns ACT and may be spaced apart from each other in the third direction D3. Filling the word line WL may include, for example, conformally depositing a gate dielectric pattern GI on an inner wall of the word line trench WTR, filling an inside of the word line trench WTR with the conductive layer, forming a gate electrode GE through an etch-back and/or grinding process for the conductive layer, and forming a gate capping pattern GC filling a remainder of the word line trench WTR on the gate electrode GE.

For example, an upper portion of the first sub-isolation pattern 111 and an upper portion of the second sub-isolation pattern 112 may be removed before, during or after forming the word line WL. For example, the first sub-isolation pattern 111 and the second sub-isolation pattern 112 may be removed from the upper surfaces of the active patterns ACT.

The first isolation pattern 110 may include a first sub-isolation pattern 111 and a second sub-isolation pattern 112 that remain after the removing of the first sub-isolation pattern 111 and the second sub-isolation pattern 112.

The device isolation patterns STI1 and STI2 may include the first isolation pattern 110 and/or the second isolation pattern 120 remaining in the active trench region AT after the processes described above. For example, the first device isolation pattern STI1 may include the first isolation pattern 110 in the first active trench region AT1. For example, the second device isolation pattern STI2 may include the first isolation pattern 110 and the second isolation pattern 120 in the second active trench region AT2.

Referring back to FIGS. 2 to 3C, a buffer layer (not shown) and a polysilicon layer (not shown) may be formed to cover the active patterns ACT, and then, first recess regions RS1 may be formed on the active patterns ACT and the device isolation patterns STI1 and STI2. When the first recess regions RS1 are formed, the buffer layer and the polysilicon layer may be partially removed to form a buffer pattern 210 and a polysilicon pattern 310.

A bit line contact DC, a first ohmic pattern 320, a bit line BL, and a bit line capping pattern 350 may be formed on the first recess region RS1. Forming the bit line contact DC, the first ohmic pattern 320, the bit line BL, and the bit line capping pattern 350 may include forming a bit line contact layer (not shown) filling the first recess region RS1, sequentially forming a first ohmic layer (not shown), a bit line layer (not shown), and a bit line capping layer (not shown) on the bit line contact layer, and etching the bit line contact layer, the first barrier layer, the bit line layer, and the bit line capping layer to form the bit line contact DC, the first ohmic pattern 320, the bit line BL, and the bit line capping pattern 350. In this case, a portion of the polysilicon pattern 310 may be further etched. In this process, a portion of an inside of the first recess region RS1 may be exposed to the outside again. A first barrier pattern (not shown) may be further formed between the bit line BL and the bit line contact DC and between the bit line BL and the polysilicon pattern 310 in forming the bit line BL.

Thereafter, a buried insulating pattern 250 may be formed and may fill the remainder of the first recess region RS1. A bit line spacer 360 may be formed to cover side surfaces of the bit line BL and the bit line capping pattern 350. The bit line spacer 360 may contact the side surfaces of the bit line BL and the bit line capping pattern 350. Forming the bit line spacer 360 may include sequentially forming a first spacer 362, a second spacer 364, and a third spacer 366 conformally covering the side surfaces of the bit line BL and the bit line capping pattern 350.

Storage node contacts BC and fence patterns FN may be formed between adjacent bit lines BL. The storage node contacts BC and fence patterns FN may be alternately arranged in the third direction D3. Prior to forming the storage node contacts BC, a second recess region RS2 may be formed on each of the pair of edge portions EA of the active pattern ACT. Each of the storage node contacts BC may fill the second recess region RS2 and may be electrically connected to a corresponding edge portion EA in the second recess region RS2. The fence patterns FN may be formed to vertically overlap the word lines WL. For example, the storage node contacts BC may be formed, and then fence patterns FN may be formed therebetween. As another example, the fence patterns FN may be formed first, and the storage node contacts BC may be formed therebetween.

In forming the storage node contacts BC, upper portions of the bit line spacers 360 may be partially removed. Accordingly, a capping spacer 370 may be further formed at a position where the bit line spacer 360 is removed. Then, a second barrier pattern 410 may be formed to conformally cover the bit line spacer 360, the capping spacer 370, and the storage node contacts BC.

Landing pads LP may be formed on the storage node contacts BC. Forming the landing pads LP may include sequentially forming a landing pad layer (not shown) and mask patterns (not shown) covering upper surfaces of the storage node contacts BC and anisotropic etching the landing pad layer using mask patterns as an etching mask to separate the landing pad layer into a plurality of landing pads LP. Through the etching the landing pad layer, a portion of the second barrier pattern 410, a portion of the bit line spacer 360, and a portion of the bit line capping pattern 350 may be further etched and exposed to the outside. An upper portion of the landing pad LP may be shifted from the storage node contact BC in the second direction D2.

According to some embodiments, the second spacer 364 may be exposed through an etching process of the landing pad layer. An etching process may be further performed on the second spacer 364 through the exposed portion of the second spacer 364, and finally, the second spacer 364 may include an air gap. However, the present disclosure is not limited thereto.

Then, a filling pattern 440 may be formed to cover the exposed portions and surround each of the landing pads LP, and a data storage pattern DSP may be formed on each of the landing pads LP.

According to the concept of the present disclosure, the interference between the word lines may be minimized by providing the shield pattern including the conductive material. In addition, the one shield pattern may surround the plurality of active patterns on the cell region and may cover the side surfaces of each of the word lines. Accordingly, the shield pattern may be electrically easily controlled. As a result, the electrical characteristics and reliability of the semiconductor device may be improved.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A semiconductor device comprising:
a substrate including cell regions;
active patterns adjacent to each other in first and second directions that are parallel to a lower surface of the substrate and intersect each other on the cell regions;
a shield pattern surrounding side surfaces of the active patterns;
a first isolation pattern surrounding the active patterns between the active patterns and the shield pattern;
second isolation patterns between adjacent active patterns in the first direction; and
word lines crossing the active patterns and the shield pattern in the second direction.

2. The semiconductor device of claim 1, wherein the shield pattern surrounds the second isolation patterns.

3. The semiconductor device of claim 1, wherein the shield pattern is interposed between the first isolation pattern and the second isolation patterns.

4. The semiconductor device of claim 1, wherein the word lines are spaced apart from each other in a third direction crossing the first and second directions, with the shield pattern interposed therebetween.

5. The semiconductor device of claim 1, wherein an uppermost surface of the shield pattern is positioned at a level higher than a lowermost surface of each of the word lines.

6. The semiconductor device of claim 1, wherein the shield pattern covers a side surface of each of the word lines.

7. The semiconductor device of claim 6, wherein the shield pattern is one shield pattern, and
wherein the one shield pattern covers side surfaces of two or more of the word lines.

8. The semiconductor device of claim 1, wherein the shield pattern is one shield pattern, and
wherein the one shield pattern surrounds side surfaces of two or more of the active patterns.

9. The semiconductor device of claim 1, further comprising:
active trench regions defined between the active patterns neighboring in the first direction,
wherein the shield pattern covers inner walls of the active trench regions,
wherein the first isolation pattern is interposed between the shield pattern and the inner walls of the active trench regions, and
wherein the second isolation patterns are surrounded by the shield pattern in the active trench region.

10. The semiconductor device of claim 1, further comprising:
active trench regions defined between active patterns neighboring in the second direction,
wherein the first isolation pattern covers inner walls of the active trench regions,
wherein the shield pattern fills insides of the active trench regions, and
wherein the second isolation patterns are not provided in the active trench regions.

11. The semiconductor device of claim 1, wherein the first isolation pattern includes a first sub-isolation pattern on a side surface of the shield pattern and a second sub-isolation pattern on an upper surface of the shield pattern.

12. The semiconductor device of claim 1, wherein the shield pattern includes a conductive material.

13. A semiconductor device comprising:
a first active pattern and a second active pattern adjacent to each other in a first direction;
a device isolation pattern surrounding the first active pattern and the second active pattern;
a word line crossing the device isolation pattern in a second direction crossing the first direction between the first active pattern and the second active pattern; and
a shield pattern between the first active pattern and the word line and between the second active pattern and the word line.

14. The semiconductor device of claim 13, wherein an uppermost surface of the shield pattern is positioned at a level higher than a lowermost surface of the word line.

15. The semiconductor device of claim 13, wherein the device isolation pattern surrounds the shield pattern.

16. The semiconductor device of claim 13, wherein the shield pattern is one shield pattern, and
wherein the one shield pattern surrounds side surfaces of the first active pattern and the second active pattern.

17. The semiconductor device of claim 13, wherein the device isolation pattern surrounds the first active pattern between the first active pattern and the shield pattern, and surrounds the second active pattern between the second active pattern and the shield pattern.

18. A semiconductor device comprising:
a substrate including a cell region;
active patterns adjacent to each other in first to third directions that are parallel to a lower surface of the substrate and intersect each other on the cell region;
a shield pattern surrounding side surfaces of the active patterns;
a first isolation pattern surrounding the active patterns between the active patterns and the shield pattern;
second isolation patterns between adjacent active patterns in the first direction;
word lines crossing the active patterns and the shield pattern in the second direction;
bit lines extending in the third direction on the active patterns;
storage node contacts interposed between adjacent bit lines on the active patterns and adjacent to each other in the second and third directions;
landing pads on the storage node contacts; and
data storage patterns on the landing pads.

19. The semiconductor device of claim 18, wherein the shield pattern is one shield pattern, and
wherein the one shield pattern covers side surfaces of two or more of the word lines.

20. The semiconductor device of claim 18, wherein the substrate further includes a peripheral region surrounding the cell region, and
wherein the semiconductor device further includes a contact pattern provided on the peripheral region and electrically connected to the shield pattern.
